(19) United States
(12) Patent Application Publication
(10) Pub. No.: US 2025/0031505 A1
(43) Pub. Date: Jan. 23, 2025

(54) LIGHT-EMITTING DIODE DRIVING BACKPLANE AND DISPLAY APPARATUS

(71) Applicants: Hefei BOE Ruisheng Technology Co., Ltd., Hefei,Anhui (CN); BOE TECHNOLOGY GROUP CO., LTD., Beijing (CN)

(72) Inventors: Wenjie XU, Beijing (CN); Xiaodong XIE, Beijing (CN); Min HE, Beijing (CN); Jing WANG, Beijing (CN); Huayu SANG, Beijing (CN); Xue ZHAO, Beijing (CN); Xinxiu ZHANG, Beijing (CN); Feifei YU, Beijing (CN)

(21) Appl. No.: 18/688,018

(22) PCT Filed: Sep. 21, 2022
(86) PCT No.: PCT/CN2022/120203

§ 371 Date: Feb. 29, 2024

(30) Foreign Application Priority Data
Dec. 15, 2021 (CN) 202111534164.9

(51) Int. Cl. H01L 33/62; H01L 25/075

(52) U.S. Cl. CPC H01L 33/62; H01L 25/0753

(57) ABSTRACT

A light-emitting diode driving backplane and a display apparatus are provided, and belong to the field of display technology. The light-emitting diode driving backplane includes: a base substrate divided into luminescent lamp regions and a first wiring region around the luminescent lamp regions; at least one pair of first connection pads, signal traces and an auxiliary functional component on the base substrate. The at least one pair of first connection pads and the auxiliary functional component are in the luminescent lamp regions, the signal traces are in the first wiring region, each pair of first connection pads includes a positive pad and a negative pad, and the signal traces are electrically connected to the corresponding positive negative pads for providing driving signals thereto, and the auxiliary functional component and at least some signal traces are in the same layer.

### TECHNICAL FIELD

The present disclosure relates to the field of display technology, and in particular to a light-emitting diode driving backplane and a display apparatus.

### BACKGROUND

The micro/mini light-emitting diode (Micro/Mini-LED) display technology, as a new generation display technology, has the advantages of high brightness, good luminous efficiency, low power consumption, and the like. The two major applications of the Mini LED are a backlight application and a display application. The backlight of the Mini LED cooperates with a traditional liquid crystal display panel to achieve display effects including high contrast, high color gamut, high brightness and high dynamic illumination rendering through local dimming. The backlight of the Mini LED is mainly applied to television, touch display, vehicle-mounted products and the like at present.

### SUMMARY

The present disclosure is directed to at least one of the technical problems of the prior art, and provides a light-emitting diode driving backplane (a backplane for driving a light-emitting diode) and a display apparatus.

In a first aspect, embodiments of the present disclosure provide a light-emitting diode driving backplane, including: a base substrate divided into a plurality of luminescent lamp regions and a first wiring region around the plurality of luminescent lamp regions; and at least one pair of first connection pads, a plurality of signal traces and an auxiliary functional component on the base substrate, wherein the at least one pair of first connection pads and the auxiliary functional component are in the plurality of luminescent lamp regions, the plurality of signal traces are in the first wiring region, each pair of first connection pads includes a positive pad and a negative pad, and the plurality of signal traces are electrically connected to the corresponding positive pads and the corresponding negative pads, and the auxiliary functional component and at least part of the plurality of signal traces are in the same layer.

In some embodiments, the at least one pair of first connection pads include a plurality of pairs of first connection pads, the light-emitting diode driving backplane further includes at least one first connection trace in the luminescent lamp regions, and in any one luminescent lamp region, one first connection trace is connected to the positive pad in one pair of first connection pads and the negative pad in the other pair of first connection pads, so that the light-emitting diodes to be mounted are connected in series.

In some embodiments, the light-emitting diode driving backplane includes: a first conductive layer including the at least one first connection trace and the auxiliary functional component.

In some embodiments, each of the luminescent lamp regions includes multiple pairs of the first connection pads arranged in an array defining a receiving region, and the auxiliary functional component in each of the luminescent lamp regions is in the receiving region.

In some embodiments, the plurality of luminescent lamp regions form a plurality of groups of lamp regions along a first direction, each group of lamp regions includes multiple luminescent lamp regions arranged side by side along a second direction, each auxiliary functional component includes a main body structure and a first connection structure surrounding the periphery of the main body structure and electrically connected to the main body structure, and the first connection structures of the auxiliary functional components adjacent to each other in the second direction are electrically connected to each other through a second connection structure.

In some embodiments, the light-emitting diode driving backplane includes: a second conductive layer on a side of the auxiliary functional component away from the base substrate and including the second connection structure and the first connection pads.

In some embodiments, the light-emitting diode driving backplane includes: a first conductive layer, a first insulating layer and a second conductive layer sequentially arranged along a direction away from the base substrate, the first conductive layer includes the auxiliary functional component and the at least one first connection trace, the second conductive layer includes the second connection structure, and the second connection structure is electrically connected to the first connection structure through a via penetrating through the first insulating layer.

In some embodiments, a minimum distance between the first connection structure and the first connection trace corresponding to each other is not less than twice a line width of the first connection structure.

In some embodiments, the plurality of luminescent lamp regions form a plurality of groups of lamp regions along a first direction, each group of lamp regions includes multiple luminescent lamp regions arranged side by side along a second direction, the plurality of signal traces include first power signal lines and second power signal lines, the first power signal lines are electrically connected to the corresponding positive connection pads, and the second power signal lines are electrically connected to the corresponding negative connection pads, the first power signal line and the second power signal line are on two opposite sides of each group of lamp regions in the first direction, respectively, and the first power signal lines and the second power signal lines are alternately arranged.

In some embodiments, the light-emitting diode driving backplane further includes: a plurality of groups of second connection pads, and the plurality of signal traces include a plurality of operation indication signal lines; and each of the plurality of groups of second connection pads is configured to electrically connect a driver chip to be mounted to the corresponding operation indication signal line and the corresponding second power signal line, so that a second power signal output by the second power signal line is output to the corresponding negative connection pad under control of the driver chip; and each driver chip is configured to control the luminescent brightness of the light-emitting diodes to be mounted in the corresponding luminescent lamp region.

In some embodiments, each group of the second connection pads includes a second power connection pad, an operation indication connection pad, an output connection pad, a control connection pad, the second power connection pad and the operation indication connection pad are arranged side by side in the second direction; the second power connection pad is electrically connected to the corresponding second power signal line through a second connection trace, and the operation indication connection pad is electrically connected to the corresponding operation indication signal line through a third connection trace; and for any group of the second connection pads, the second power signal line electrically connected to the second power connection pad and the operation indication signal line electrically connected to the operation indication connection pad are on the same side of a group of lamp regions, the operation indication signal line includes signal line segments arranged at intervals and connection line segments each electrically connecting the adjacent signal line segments, and an orthographic projection of the connection line segments on the base substrate crosses with an orthographic projection of the second connection traces on the base substrate.

In some embodiments, the light-emitting diode driving backplane includes: a first conductive layer, a first insulating layer and a second conductive layer sequentially arranged along a direction away from the base substrate, the first conductive layer includes the auxiliary functional component, the first power signal lines, the second power signal lines, the second connection traces, the third connection trace, and the signal line segments, and the second conductive layer includes the second power connection pads, the operation indication connection pads, the output connection pads, the control connection pads, and the connection line segments.

In some embodiments, for any one group of the lamp regions, the control connection pad corresponding to the N^{th} luminescent lamp region is connected to the output connection pad connected to the negative connection pad in the (N+1)^{th} luminescent lamp region via a fourth connection trace, N is an integer greater than or equal to 1.

In some embodiments, the first conductive layer further includes the third connection trace.

In some embodiments, the auxiliary functional component includes an antenna array.

In some embodiments, the auxiliary functional component includes a conductive mesh structure.

In some embodiments, the base substrate further includes a bonding region provided with a third connection pad, and the signal traces extend from the first wiring region to the bonding region and are electrically connected to the third connection pad.

In some embodiments, the light-emitting diode driving backplane includes: a first conductive layer, a first insulating layer and a second conductive layer sequentially arranged along a direction away from the base substrate, the first conductive layer includes the auxiliary functional component, and the second conductive layer includes the first connection pad and the third connection pad.

In some embodiments, the light-emitting diode driving backplane is a backlight.

In a second aspect, embodiments of the present disclosure provide a display apparatus, which includes the light-emitting diode driving backplane in any one of the embodiments.

### BRIEF DESCRIPTION OF DRAWINGS

FIG. 1 is a schematic diagram of a light-emitting diode backplane according to an embodiment of the present disclosure.

FIG. 2 is a schematic plan view of a portion of a light-emitting diode backplane according to an embodiment of the present disclosure.

FIG. 3 is a schematic diagram of a millimeter wave antenna array of a light-emitting diode backplane according to an embodiment of the present disclosure.

FIG. 4 is a cross-sectional view of the light-emitting diode driving backplane along a line A-A′ in FIG. 2.

FIG. 5 is a schematic plan view of a portion of a light-emitting diode backplane according to an embodiment of the present disclosure.

FIG. 6 is a schematic diagram illustrating connection of a light-emitting diode backplane at a position of a group of second connection pads according to an embodiment of the present disclosure.

FIG. 7 is a cross-sectional view of the light-emitting diode driving backplane along a line B-B′ in FIG. 2.

FIG. 8 is a schematic plan view of a portion of a light-emitting diode backplane according to an embodiment of the present disclosure.

FIG. 9 is a cross-sectional view of a light-emitting diode backplane at a location of a third connection pad according to an embodiment of the present disclosure.

FIG. 10 is a flowchart of a method for manufacturing a light-emitting diode backplane according to an embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term “comprising”, “including”, or the like means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

In a first aspect, the embodiment of the present disclosure provides a light-emitting diode driving backplane, which may be applied to a backlight and a display. In the embodiment of the present disclosure, as an example, the light-emitting diode driving backplane is applied to the backlight. That is, the light-emitting diode driving backplane may be at least a part of a structure of a backlight source. In particular, an auxiliary functional component including, but not limited to, a millimeter wave antenna array 2 is integrated in the light-emitting diode driving backplane of the embodiment of the present disclosure. When the auxiliary functional component is the millimeter wave antenna array 2, a display apparatus including the light-emitting diode driving backplane can realize a space-free man-machine interaction, such as gesture recognition. In the following description, the auxiliary functional component is as the millimeter wave antenna array 2 as an example. The light-emitting diode driving backplane in the embodiments of the present disclosure is specifically described below.

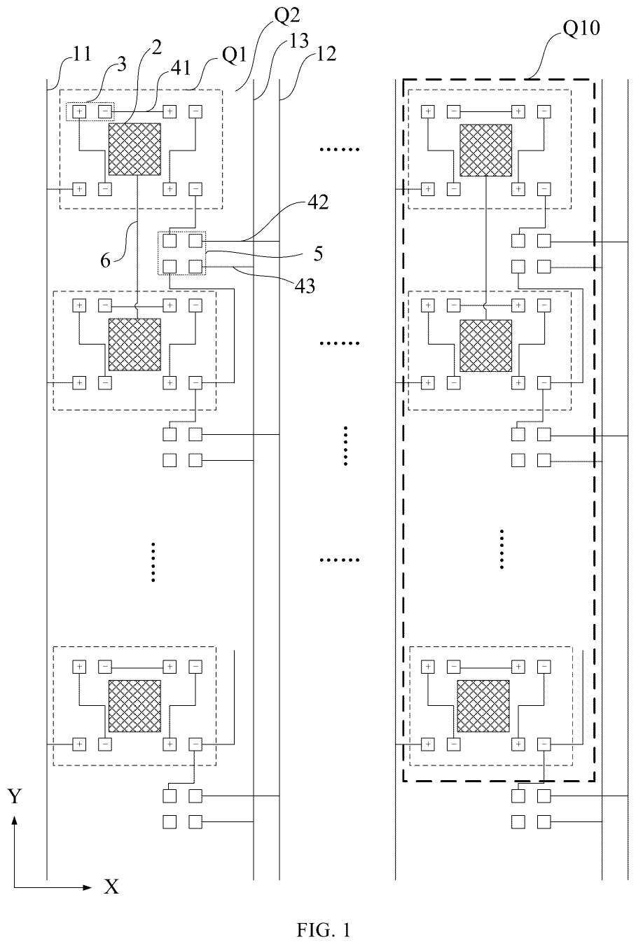

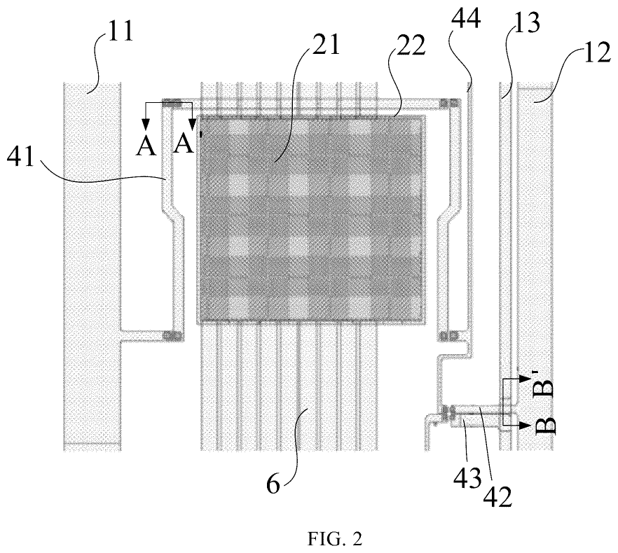

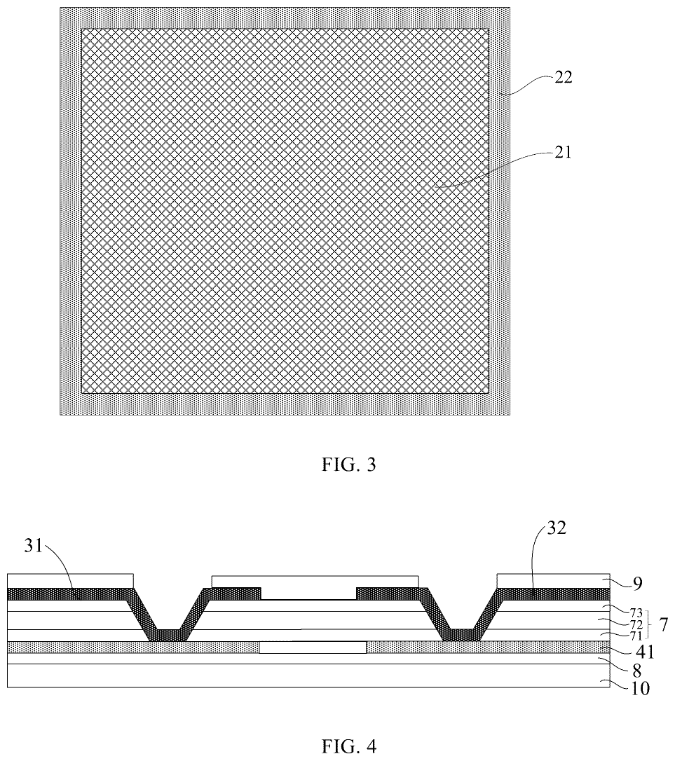

FIG. 1 is a schematic diagram of a light-emitting diode backplane according to an embodiment of the present disclosure. FIG. 2 is a schematic plan view of a portion of a light-emitting diode backplane according to an embodiment of the present disclosure. FIG. 3 is a schematic diagram of a millimeter wave antenna array 2 of a light-emitting diode backplane according to an embodiment of the present disclosure. FIG. 4 is a cross-sectional view of the light-emitting diode driving backplane along a line A-A′ in FIG. 2. As shown in FIGS. 1 to 4, the light-emitting diode driving backplane in the embodiment of the present disclosure may include a base substrate 10, and at least one pair of first connection pads 3, a plurality of signal traces (lines), and millimeter wave antenna arrays 2 disposed on the base substrate 10. The base substrate 10 is divided into a functional region and a bonding region disposed on at least one side of the functional region, and the functional region is divided into a plurality of luminescent lamp regions Q1 and a first wiring region Q2 located around the luminescent lamp regions Q1. Each luminescent lamp region Q1 is further provided with at least one pair of first connection pads 3, including a positive connection pad 31 and a negative connection pad 32 electrically connecting to positive electrodes and negative electrodes of light-emitting diodes to be mounted, respectively. Each luminescent lamp region Q1 is further provided with one millimeter wave antenna array 2 for receiving and transmitting signals. The signal traces are disposed in the first wiring region Q2, and are configured to be electrically connected to the corresponding positive connection pads 31 and the corresponding negative connection pads 32, and provide driving signals to the corresponding positive connection pads 31 and the corresponding negative connection pads 32, so as to drive the mounted light-emitting diodes to emit light.

Therefore, the millimeter wave antenna array 2 is arranged in each luminescent lamp region Q1 of the light-emitting diode driving backplane according to the embodiment of the present disclosure, so that when the backplane is applied to the display apparatus, the millimeter wave antenna array 2 may be controlled to operate to realize the receiving and transmitting of signals, thereby realizing the functions such as the gesture recognition and the like.

In some examples, each of the luminescent lamp regions Q1 includes a plurality of pairs of first connection pads 3. It is understood that each pair of first connection pads 3 is configured to be electrically connected to one light-emitting diode while each luminescent lamp region Q1 includes the plurality of pairs of first connection pads 3. That is, a plurality of light-emitting diodes may be mounted in each of the luminescent lamp regions Q1. The backplane of the embodiment of the present disclosure may be used as a backlight source of the display apparatus. In order to realize the luminescent brightness, the plurality of light-emitting diodes mounted in each of the luminescent lamp regions Q1 are uniformly arranged, for example, in an array. Therefore, the plurality of pairs of first connection pads 3 in each of the luminescent lamp regions Q1 are preferably uniformly arranged, for example, in an array. In FIG. 1, as an example, each of the luminescent lamp regions Q1 includes four pairs of first connection pads 3 arranged in a 2×2 array. Further, a region defined by the four pairs of first connection pads 3 has a rectangular shape, and the millimeter wave antenna array 2 is disposed in the rectangular region. With such the arrangement, the millimeter wave antenna arrays 2 in the backplane may be uniformly arranged in an array, so that the induction uniformity is ensured. It should be noted that in the embodiment of the present disclosure, only four pairs of first connection pads 3 are arranged in each luminescent lamp region Q1 shown in FIG. 1, and the region defined by the four pairs of first connection pads 3 has the rectangular shape as an example. In an actual product, the number of pairs of first connection pads 3 in each luminescent lamp region Q1 is not limited to four, and the shape of the defined region is not limited to a rectangle, which is not specifically limited in the embodiment of the present disclosure.

With continued reference to FIG. 2, each of the luminescent lamp regions Q1 includes not only the plurality of pairs of first connection pads 3, but also a first connection trace 41 for connecting light-emitting diodes in series each electrically connected to one pair of first connection pads 3. Specifically, each first connection trace 41 may electrically connect the positive connection pad 31 of one of two pairs of first connection pads 3 and the negative connection pad 32 of the other of the two pairs of first connection pads 3. In some examples, a first conductive layer is provided on the base substrate 10, and includes the first connection traces 41 and the millimeter wave antenna arrays 2, that is, the first connection traces 41 and the millimeter wave antenna arrays 2 are disposed in the same layer and are made of the same material, so that a pattern including the first connection traces 41 and the millimeter wave antenna arrays 2 may be formed by using a one-step patterning process.

Further, the plurality of luminescent lamp regions Q1 in the backplane of the embodiment of the present disclosure are arranged in an array, to form a plurality of groups of lamp regions Q10 arranged side by side along a first direction X, and each group of lamp regions Q10 includes luminescent lamp regions Q1 arranged side by side along a second direction Y. Each millimeter wave antenna array 2 includes a main body structure 21 and a first connection structure 22 surrounding the periphery of the main body structure 21 and electrically connected to the main body structure 21. The first connection structure 22 may be used as transmission lines of the millimeter wave antenna array 2. In each group of the lamp regions Q10, the first connection structures 22 of the adjacent millimeter wave antenna arrays 2 are electrically connected to each other through second connection structures 6. In some examples, in order to ensure better electrical connection of the millimeter wave antenna arrays 2, a plurality of second connection structures 6 may be provided for electrically connecting any two adjacent first connection structures 22. In some examples, an orthographic projection of each second connection structure 6 on the base substrate 10 overlaps with orthographic projections of the first connection structures 22 electrically connected to the second connection structure 6 on the base substrate 10, and does not overlap with an orthographic projection of the main body structure 21 on the base substrate 10. Of course, the second connection structures 6 in the embodiment of the present disclosure only need to ensure that the adjacent millimeter wave antenna arrays 2 may be well electrically connected to each other, to transmit the microwave signal in each group of lamp regions Q10.

In the embodiment of the present disclosure, each millimeter wave antenna array 2 is located in the region defined by the plurality of pairs of first connection pads 3 in the corresponding luminescent lamp region Q1, and the light-emitting diodes in series each electrically connected to one pair of first connection pads 3 are connected to each other in series through the first connection trace 41. At this time, each millimeter wave antenna array 2 is defined in the region defined by the first connection trace 41. The first connection trace 41 is used for transmitting an electrical signal for driving the light-emitting diode to emit light, so that in order to avoid interference between the first connection trace 41 and the first connection structure 22 of the millimeter wave antenna array 2, a distance between the first connection trace 41 and the first connection structure 22 needs to be set reasonably. In some examples, the minimum distance between the first connection trace 41 and the first connection structure 22 is twice a line width of the first connection structure 22. For example: the line width of the first connection structure 22 is about 100 μm, and the minimum distance between the first connection trace 41 and the first connection structure 22 is not less than 200 μm. In some examples, the main body structure 21 of the millimeter wave antenna array 2 adopts a conductive mesh structure, and a maximum width of each hollow part of the conductive mesh structure is in a range from 50 μm to 100 μm. Any interior angle of each hollow part is in a range from 80° to 90°. Each hollow part has a diamond shape as an example, each of a pair of opposite angles is in a range from 80° to 90°, and each of the other pair of opposite angles is in a range from 90° to 100°.

In some examples, the backplane in embodiments of the present disclosure includes a first conductive layer, a first insulating layer 7 and a second conductive layer arranged sequentially along the direction away from the base substrate 10. The first conductive layer includes the first connection traces 41, the main structures 21 and the first connection structures 22 of the millimeter wave antenna arrays 2, and the second conductive layer includes the second connection structures 6 and the plurality of pairs of first connection pads 3. At this time, the first connection pads 3 need to be electrically connected to the corresponding first connection traces 41 through vias penetrating through the first insulating layer 7, and the second connection structures 6 need to be electrically connected to the corresponding first connection structures 22 through vias penetrating through the first insulating layer 7.

With continued reference to FIG. 2, the signal traces of the backplane in the embodiment of the present disclosure at least include a plurality of first power signal lines 11 and a plurality of second power signal lines 12. For each luminescent lamp region Q1, a positive connection pad 31 not connected to the first connection trace 41 is connected to the corresponding first power signal line 11, and a negative connection pad 32 not connected to the first connection trace 41 is connected to the corresponding second power signal line 12. Since the second power signal line 12 is connected to the corresponding cathode connection pad 32, the second power signal line 12 may be a ground signal line. For the sake of clarity, in each of the luminescent lamp regions Q1, the positive connection pad 31 connected to the first power signal line 11 is referred to as a first positive connection pad 31, and the negative connection pad 32 connected to the second power signal line 12 is referred to as a last negative connection pad 32. Operating voltage is supplied to the light-emitting diodes mounted in the luminescent lamp regions Q1 through voltage signals outputted from the first power signal lines 11 and the second power signal lines 12 to control the operation of the light-emitting diodes.

Further, in the luminescent lamp regions Q1 in each group of lamp regions Q10, the first positive connection pads 31 are electrically connected to the same first power supply signal line 11, and the last negative connection pads 32 are electrically connected to the same second power supply signal line 12. In some examples, the first power signal line and the second power signal line 12 electrically connected to each group of the lamp regions Q10 are respectively disposed on two opposite sides of the group of the lamp regions Q10 in the first direction X, so that the wiring is more uniform and more convenient in the backplane.

Further, in some examples, the first power signal lines 11 and the second power signal lines 12 are located in the same layer and made of the same material. For example: the first power signal lines 11 and the second power signal lines 12 are both disposed in the same layer as the millimeter wave antenna arrays 2, that is, the first power signal lines 11 and the second power signal lines 12 may also belong to a part of the structure of the first conductive layer. Therefore, the lightweight and thinness design of the light-emitting diode driving backplane is easily achieved.

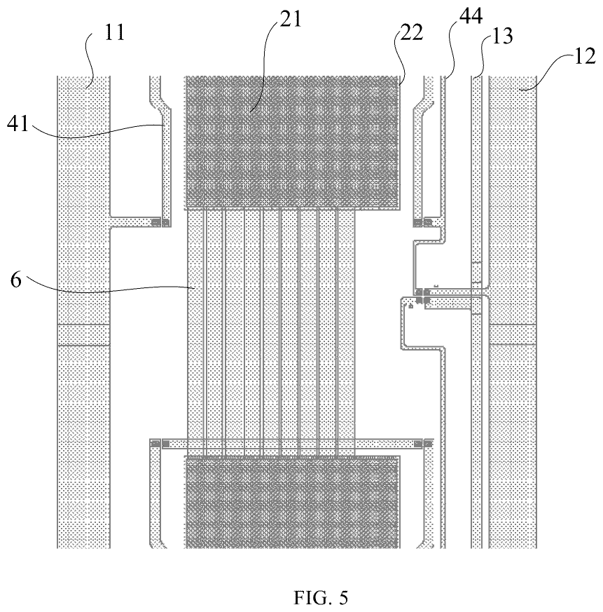

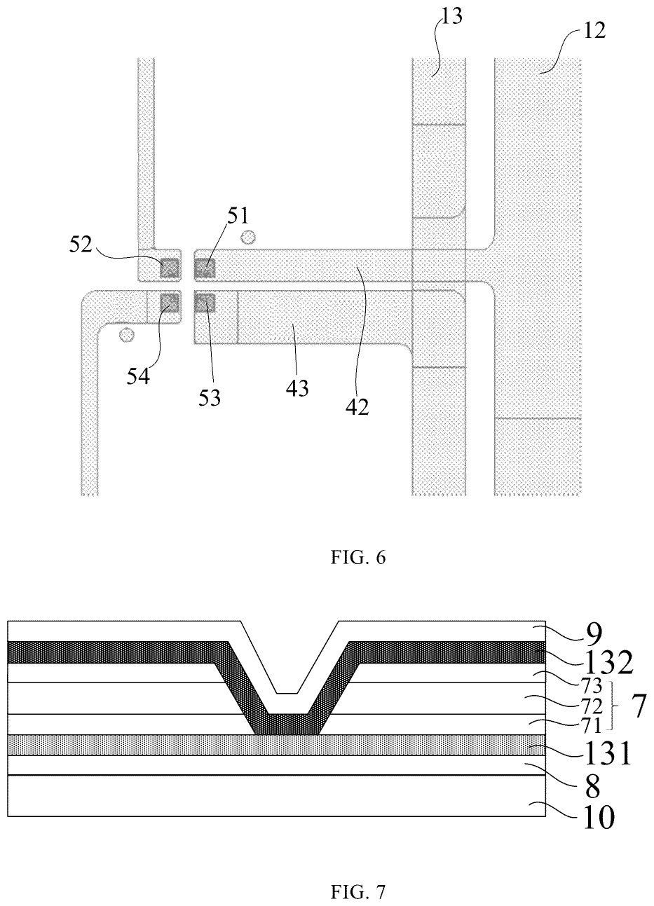

In some examples, FIG. 5 is a schematic plan view of a portion of a light-emitting diode backplane according to an embodiment of the present disclosure. FIG. 6 is a schematic diagram illustrating connection of a light-emitting diode backplane at a position of a group of second connection pads 5 according to an embodiment of the present disclosure. FIG. 7 is a cross-sectional view of the light-emitting diode driving backplane along a line B-B′ in FIG. 2. As shown in FIGS. 5 to 7, the embodiment of the present disclosure further provides a light-emitting diode backplane capable of adjusting brightness, which includes not only the above structure, but also a plurality of groups of second connection pads 5 disposed in one-to-one correspondence with the luminescent lamp regions Q1; the signal traces includes not only the first power signal lines 11 and the second power signal lines 12 described above but also operation indication signal lines 13. Each group of the second connection pads 5 is configured to be electrically connected to one driver chip and to the operation indication line and the second power signal line 12 corresponding to the driver chip, a signal output by the operation indication line is configured to supply power to the driver chip connected to the operation indication line, and a second power signal output by the second power signal line 12 is output to the corresponding negative connection pad 32 under the control of the driver chip. Each of the driver chips is configured to control the luminescent brightness of the light-emitting diodes to be mounted in the corresponding luminescent lamp region Q1.

For example: referring to FIGS. 5 to 7, each group of the second connection pads 5 includes four connection pads, namely a second power connection pad 51, an operation indication connection pad 53, an output connection pad 52, and a control connection pad 54 arranged in a 2×2 array, where the second power connection pad 51 and the operation indication connection pad 53 are arranged side by side in the second direction Y, the output connection pad 52 and the control connection pad 54 are arranged side by side in the second direction Y, the second power connection pad 51 and the output connection pad 52 are arranged side by side in the first direction X, and the control connection pad 54 and the operation indication pad are arranged side by side in the first direction X. For each group of the second connection pads 5, the second power connection pad 51 is electrically connected to the second power signal line 12 through the second connection trace 42, the operation indication connection pad 53 is electrically connected to the operation indication signal line 13 through a third connection trace 43, and the second power signal line 12 and the operation indication signal line 13 are located on the same side of a group of lamp regions Q10. The operation indication signal line 13 includes signal line segments 131 arranged at intervals, and connection line segments 132 each electrically connecting the adjacently arranged signal line segments 131. An orthographic projection of the connection line segments 132 on the base substrate 10 crosses with an orthographic projection of the second connection traces 42 on the base substrate 10. It should be noted that in order to avoid a short circuit between the second power signal lines 12 and the operation indication signal lines 13, an insulating material is disposed between the connection line segments 132 and the second connection traces 42. It can be seen that in the embodiment of the present disclosure, orthographic projections of the second power signal lines 12 and the operation indication signal lines 13 on the base substrate 10 are arranged side by side, and do not overlap with each other. At this time, after the driver chips are mounted, no matter the second power signal lines 12 and the operation indication signal lines 13, there is no overlap between the driver chip and each of the second power signal lines 12 and the operation indication signal lines 13 except for their connection ends, so that a distance between pins inside the driver chip does not need to be increased, and the orthographic projections of the second power signal lines 12 and the operation indication signal lines 13 on the base substrate 10 are arranged side by side, which can effectively eliminate the problems of short circuit and signal crosstalk.

Further, with continued reference to FIGS. 5 to 7, for the convenience of wiring and control, for any one group of lamp regions Q10, the control connection pad 54 corresponding to the N^{th} luminescent lamp region Q1 is connected to the output connection pad 52 connected to the negative connection pad 32 in the (N+1)^{th} luminescent lamp region Q1 through a fourth connection trace 44; N is an integer greater than or equal to 1. It can be seen that after the driver chips are mounted on the backplane, the driver chips corresponding to each group of the lamp regions Q10 are connected in series, so that the luminescent brightness of the light-emitting diodes in the backplane is more convenient to control.

Further, with continued reference to FIGS. 5 to 7, the signal line segments 131 of the operation indication signal lines 13, the second connection traces 42, the third connection traces 43, and the fourth connection traces 44 may be disposed in the same layer as the second power signal lines 12, and the connection line segments 132 of the operation indication signal lines 13 are disposed in the same layer as the plurality of groups of first connection pads 3 and the plurality of groups of second connection pads 5. That is, the first conductive layer includes not only the first power signal lines 11, the second power signal lines 12, the first connection traces 41 and the millimeter wave antenna arrays 2, but also the signal line segments 131 of the operation indication signal lines 13. The second conductive layer includes not only the plurality of groups of the first connection pads 3, the plurality of groups of the second connection pads 5, the second connection structures 6, but also the connection line segments 132 of the operation indication signal lines 13. Therefore, the lightweight and thinness design of the light-emitting diode backplane can be easily achieved.

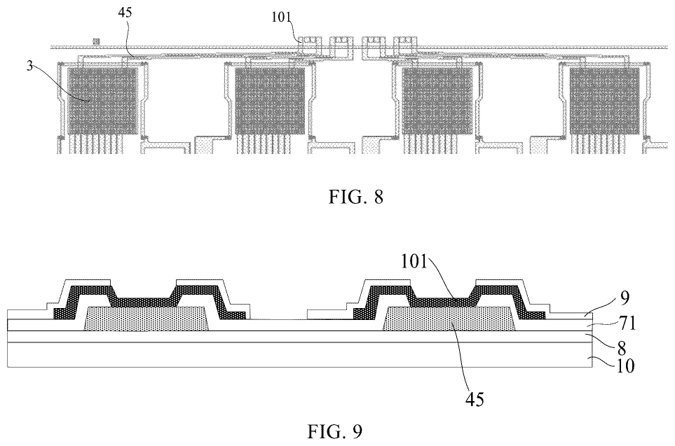

In some examples, FIG. 8 is a schematic plan view of a portion of a light-emitting diode backplane according to an embodiment of the present disclosure. FIG. 9 is a cross-sectional view of a light-emitting diode backplane at a location of a third connection pad 101 according to an embodiment of the present disclosure. As shown in FIGS. 8 and 9, the light-emitting diode backplane of the embodiment of the present disclosure includes not only the above structure but also a plurality of third connection pads 101 located in the bonding region. The signal traces extend from the first wiring regions Q2 to the bonding region and are electrically connected to the third connection pads 101. For example: the first power signal lines 11, the second power signal lines 12, the operation indication signal lines 13, and the millimeter wave antenna arrays 2 are electrically connected to the third connection pads 101 corresponding to the bonding region through fifth connection traces 45.

Furthermore, a width of each third connection pad 101 in the binding region is in a range from 10 μm to 15 μm, and a distance between any two adjacent third connection pads 101 is in a range from 10 μm to 15 μm.

Further, in the embodiment of the present disclosure, the third connection pads 101, the plurality of groups of first connection pads 3 and the plurality of groups of second connection pads 5 may be disposed in the same layer, and made of the same material. That is, the second conductive layer may include not only the plurality of groups of first connection pads 3, the plurality of groups of second connection pads 5, the second connection structures 6, and the connection line segments 132 of the operation indication signal lines 13, but also the third connection pads 101. With such the arrangement, the backplane is convenient to manufacture and the process cost cannot be increased. It should be noted that when the third connection pads 101 are electrically connected to the corresponding signal traces necessarily through vias penetrating through the first insulating layer 7. The first insulating layer 7 may only include a first passivation layer 71 in the bonding region.

In some examples, the first conductive layer and the second conductive layer may be a single layer or a composite layer, which may be made of a metal material. A material of the first conductive layer includes, but is not limited to, at least any one of titanium (Ti), molybdenum (Mo), nickel (Ni), niobium (Nb), copper (Cu), and silver (Ag), gold (Au). For example: the first conductive layer includes: MoNb/Cu/MoNb, MoNb/Cu; the second conductive layer includes MoNb/Ni. In some examples, a thickness of the first conductive layer is not less than 0.3 μm, further not less than 2.7 μm. A thickness of the second conductive layer is in a range from about 1000 Å to 6000 Å.

In some examples, the first insulating layer 7 may include the first passivation layer 71, a planarization layer 72, and a second passivation layer 73 sequentially disposed along a direction away from the base substrate 10. In some examples, the first passivation layer 71 and the second passivation layer 73 may be made of inorganic materials, and may be made of the same material or different materials. The inorganic materials include: SiNx, SiNOx, and SiOx. The first passivation layer 71 and the second passivation layer 73 may be a single layer structure or a stacked-layer structure made of one or more materials of SiNx, SiNOx, and SiOx. Thicknesses of the first passivation layer 71 and the second passivation layer 73 are both in a range from about 2000 Å to about 4000 Å. The planarization layer 72 is made of an organic material. The organic material includes photosensitive OC material such as: acrylic-based polymer, or silicon-based polymer, or the like. A thickness of the planarization layer 72 is in a range from 2 μm to 5 μm, for example, 3 μm.

In some examples, the light-emitting diode backplane of the embodiments of the present disclosure includes not only the above structure, but also an anti-stress layer 8 disposed between the first conductive layer and the base substrate 10, which can effectively prevent the base substrate 10 from being rolled up and broken when the first conductive layer is formed. A material of the anti-stress layer 8 may be an inorganic material, such as: SiNx. A thickness of the anti-stress layer 8 is in a range from about 1000 Å to about 3000 Å.

In some examples, the light-emitting diode backplane of the embodiment of the present disclosure includes not only the above structure, but also a protective layer 9 disposed on a side of the second conductive layer away from the base substrate 10, where a material of the protective layer 9 may be an inorganic material, such as SiNx. A thickness of the protective layer 9 is not less than 1200 Å. It should be noted that the protective layer 9 is provided with openings at positions corresponding to the first connection pads 3, the second connection pads 5 and the third connection pads 101, so that the first connection pads 3 are welded to the light-emitting diodes, the second connection pads 5 are welded to the driver chips, and the third connection pads 101 are bound to an external printed circuit board or a flexible printed circuit board. The openings of the protective layer 9 at the positions corresponding to the first connection pads 3, the second connection pads 5 and the third connection pads 101 each have an opening size not less than 30 μm×30 μm.

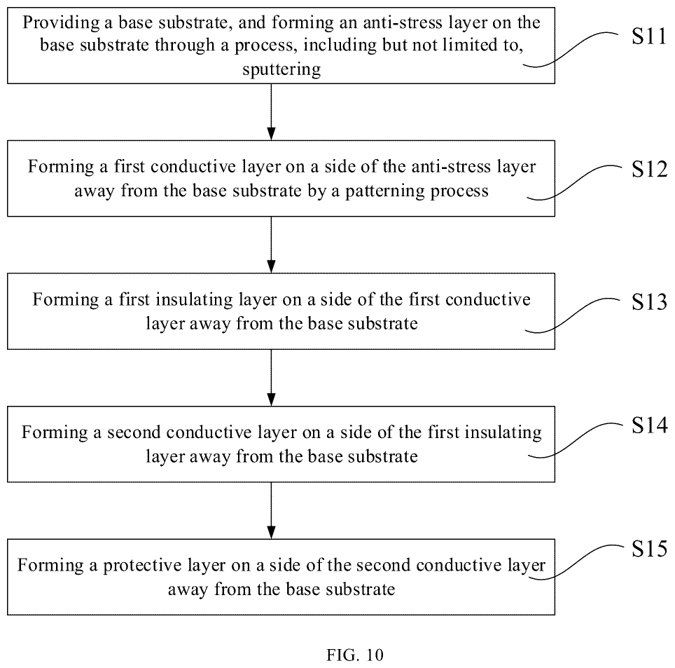

In order to make the structure of the light-emitting diode backplane of the embodiments of the present disclosure more clear, the following description is made in conjunction with the method for manufacturing the backplane. FIG. 10 is a flowchart of a method for manufacturing a light-emitting diode backplane according to an embodiment of the present disclosure. As shown in FIG. 10, the method for manufacturing a light-emitting diode backplane in the embodiment of the present disclosure may specifically include the following steps S11 to S15.

The step S11 includes providing a base substrate 10, and forming an anti-stress layer 8 on the base substrate 10 through a process, including but not limited to, sputtering.

The step S12 includes forming a first conductive layer on a side of the anti-stress layer 8 away from the base substrate 10 by a patterning process. The first conductive layer includes: first power signal lines 11, second power signal lines 12, signal line segments 131 of operation indication signal lines 13, first connection traces 41, second connection traces 42, third connection traces 43, fourth connection traces 44, and millimeter wave antenna arrays 2.

The step S13 includes forming a first insulating layer 7 on a side of the first conductive layer away from the base substrate 10.

In the step S13 of forming the first insulating layer 7 may include sequentially forming a first passivation layer 71, a planarization layer 72, and a second passivation layer 73.

The step S14 includes forming a second conductive layer on a side of the first insulating layer 7 away from the base substrate 10. The second conductive layer includes a plurality of pairs of first connection pads 3, a plurality of pairs of second connection pads 5, third connection pads 101, second connection structures 6, and connection line segments 132 of the operation indication signal lines 13.

The step S15 includes forming a protective layer 9 on a side of the second conductive layer away from the base substrate 10.

It should be noted that patterns of the first conductive layer, the first insulating layer 7, the second conductive layer and the protective layer 9 are the same as those of the product, and therefore are not described herein again.

In addition, after the above steps are completed, the method may further include back-end manufacturing steps, for example: cutting, coating of a reflective layer (white oil coating), die bonding, reflow soldering, detecting, coating protective glue and point repairing, subsequent bonding process and the like. These conventional steps will not be described in detail herein.

In a second aspect, an embodiment of the present disclosure further provides a display apparatus, which includes the light-emitting diode driving backplane. In some embodiments, the display apparatus further includes light-emitting elements including: Micro-LED chips or Mini-LED chips.

In the embodiments of the present disclosure, the light-emitting elements and the light-emitting diode driving backplane may constitute a light source with other optical structures (e.g., a light guide plate, a diffuser sheet, etc.) to provide light for a display panel in the display apparatus. Alternatively, the light-emitting elements and the light-emitting diode driving backplane are used as a part of the display panel in the display apparatus, for directly displaying the picture.

In some embodiments, the display apparatus may be any product or component having a display function, such as a mobile phone, a tablet computer, a television, a display, a notebook computer, a digital photo frame, or a navigator, or the like.

It should be understood that the above embodiments are merely exemplary embodiments adopted to explain the principles of the present disclosure, and the present disclosure is not limited thereto. It will be apparent to one of ordinary skill in the art that various changes and modifications may be made therein without departing from the spirit and scope of the present disclosure, and such changes and modifications also fall within the scope of the present disclosure.

1. A light-emitting diode driving backplane, comprising:
a base substrate divided into a plurality of luminescent lamp regions and a first wiring region around the plurality of luminescent lamp regions; and
at least one pair of first connection pads, a plurality of signal traces and an auxiliary functional component on the base substrate, wherein the at least one pair of first connection pads and the auxiliary functional component are in the plurality of luminescent lamp regions, the plurality of signal traces are in the first wiring region, each pair of first connection pads comprises a positive pad and a negative pad, and the plurality of signal traces are electrically connected to the corresponding positive pads and the corresponding negative pads, and the auxiliary functional component and at least a part of the plurality of signal traces are in a same layer.

2. The light-emitting diode driving backplane of claim 1, wherein the at least one pair of first connection pads comprise a plurality of pairs of first connection pads, the light-emitting diode driving backplane further comprises at least one first connection trace in the luminescent lamp regions, and in any one luminescent lamp region, one first connection trace is connected to the positive pad in one pair of first connection pads and the negative pad in the other pair of first connection pads, so that the light-emitting diodes to be mounted are connected in series.

3. The light-emitting diode driving backplane of claim 2, wherein the light-emitting diode driving backplane comprises: a first conductive layer comprising the at least one first connection trace and the auxiliary functional component.

4. The light-emitting diode driving backplane of claim 2, wherein each of the luminescent lamp regions comprises multiple pairs of the first connection pads arranged in an array defining a receiving region, and the auxiliary functional component in each of the luminescent lamp regions is in the receiving region.

5. The light-emitting diode driving backplane of claim 4, wherein the plurality of luminescent lamp regions form a plurality of groups of lamp regions along a first direction, each group of lamp regions comprises multiple luminescent lamp regions arranged side by side along a second direction, each auxiliary functional component comprises a main body structure and a first connection structure surrounding a periphery of the main body structure and electrically connected to the main body structure, and the first connection structures of the auxiliary functional components adjacent to each other in the second direction are electrically connected to each other through a second connection structure.

6. The light-emitting diode driving backplane of claim 5, wherein the light-emitting diode driving backplane comprises: a second conductive layer on a side of the auxiliary functional component away from the base substrate and comprising the second connection structure and the first connection pads.

7. The light-emitting diode driving backplane of claim 5, wherein the light-emitting diode driving backplane comprises: a first conductive layer, a first insulating layer and a second conductive layer sequentially arranged along a direction away from the base substrate, the first conductive layer comprises the auxiliary functional component and the at least one first connection trace, the second conductive layer comprises the second connection structure, and the second connection structure is electrically connected to the first connection structure through a via penetrating through the first insulating layer.

8. The light-emitting diode driving backplane of claim 7, wherein a minimum distance between the first connection structure and the first connection trace corresponding to each other is not less than twice a line width of the first connection structure.

9. The light-emitting diode driving backplane of claim 1, wherein the plurality of luminescent lamp regions form a plurality of groups of lamp regions along a first direction, each group of lamp regions comprises multiple luminescent lamp regions arranged side by side along a second direction, the plurality of signal traces comprise first power signal lines and second power signal lines, the first power signal lines are electrically connected to the corresponding positive connection pads, and the second power signal lines are electrically connected to the corresponding negative connection pads, the first power signal line and the second power signal line are on two opposite sides of each group of lamp regions in the first direction, respectively, and the first power signal lines and the second power signal lines are alternately arranged.

10. The light-emitting diode driving backplane of claim 9, wherein the light-emitting diode driving backplane further comprises: a plurality of groups of second connection pads, and the plurality of signal traces comprise a plurality of operation indication signal lines; and
each of the plurality of groups of second connection pads is configured to electrically connect a driver chip to be mounted to the corresponding operation indication signal line and the corresponding second power signal line, so that a second power signal output by the second power signal line is output to the corresponding negative connection pad under control of the driver chip; and each driver chip is configured to control a luminescent brightness of the light-emitting diodes to be mounted in the corresponding luminescent lamp region.

11. The light-emitting diode driving backplane of claim 10, wherein each group of the second connection pads comprises a second power connection pad, an operation indication connection pad, an output connection pad, and a control connection pad, the second power connection pad and the operation indication connection pad are arranged side by side in the second direction; the second power connection pad is electrically connected to the corresponding second power signal line through a second connection trace, and the operation indication connection pad is electrically connected to the corresponding operation indication signal line through a third connection trace; and
for any group of the second connection pads, the second power signal line electrically connected to the second power connection pad and the operation indication signal line electrically connected to the operation indication connection pad are on a same side of one group of luminescent lamp regions, the operation indication signal line comprises signal line segments arranged at intervals and connection line segments each electrically connecting two adjacent signal line segments, and an orthographic projection of the connection line segments on the base substrate crosses with an orthographic projection of the second connection traces on the base substrate.

12. The light-emitting diode driving backplane of claim 11, wherein the light-emitting diode driving backplane comprises: a first conductive layer, a first insulating layer and a second conductive layer sequentially arranged along a direction away from the base substrate, the first conductive layer comprises the auxiliary functional component, the first power signal line, the second power signal line, the second connection trace, the third connection trace, and the signal line segment, and the second conductive layer comprises the second power connection pad, the operation indication connection pad, the output connection pad, the control connection pad, and the connection line segment.

13. The light-emitting diode driving backplane of claim 12, wherein for any group of the luminescent lamp regions, the control connection pad corresponding to the N^{th} luminescent lamp region is electrically connected to the output connection pad connected to the negative connection pad in the (N+1)^{th} luminescent lamp region via a fourth connection trace, where N is an integer greater than or equal to 1.

14. The light-emitting diode driving backplane of claim 13, wherein the first conductive layer further comprises the third connection trace.

15. The light-emitting diode driving backplane of claim 1, wherein the auxiliary functional component comprises an antenna array.

16. The light-emitting diode driving backplane of claim 1, wherein the auxiliary functional component comprises a conductive mesh structure.

17. The light-emitting diode driving backplane of claim 1, wherein the base substrate further comprises a bonding region provided with a third connection pad, and the plurality of signal traces each extend from the first wiring region to the bonding region and are electrically connected to the third connection pad.

18. The light-emitting diode driving backplane of claim 17, wherein the light-emitting diode driving backplane comprises: a first conductive layer, a first insulating layer and a second conductive layer sequentially arranged along a direction away from the base substrate, and the first conductive layer comprises the auxiliary functional component, and the second conductive layer comprises the first connection pad and the third connection pad.

19. The light-emitting diode driving backplane of claim 1, wherein the light-emitting diode driving backplane is a backlight.

20. A display apparatus, comprising the light-emitting diode driving backplane of claim 1.
